(19) United States
(12) Patent Application Publication
(10) Pub. No.: US 2025/0370487 A1
(43) Pub. Date: Dec. 4, 2025

(54) INFORMATION PROCESSING APPARATUS, TEMPERATURE CONTROL METHOD, AND HEAT TREATMENT APPARATUS

(71) Applicant: Tokyo Electron Limited, Tokyo (JP)

(72) Inventors: Tadashi ENOMOTO, Iwate (JP); Daigo FURUYA, Iwate (JP); Koma SASAKI, Yamanashi (JP)

(21) Appl. No.: 19/219,150

(22) Filed: May 27, 2025

(30) Foreign Application Priority Data
Jun. 3, 2024 (JP) 2024-089879

(51) Int. Cl. G05D 23/19; H01L 21/67

(52) U.S. Cl. CPC G05D 23/1902; H01L 21/67109

(57) ABSTRACT

An information processing apparatus includes: a measured temperature acquisition unit that acquires a measured temperature of a member that holds a substrate to be processed and is carried into and out of a processing container of a heat treatment apparatus, before the member is carried into the processing container; a prediction unit that outputs a predicted temperature of the substrate to be processed after the member is carried into the processing container, using the measured temperature of the member and a thermal simulation model of the heat treatment apparatus; and an adjustment unit that outputs a set temperature, adjusted based on the predicted temperature of the substrate to be processed, to a temperature controller that controls a heating unit to heat the interior of the processing container such that a measured temperature inside the processing container approaches the set temperature.

### CROSS-REFERENCE TO RELATED APPLICATIONS

This application is based on and claims priority from Japanese Patent Application No. 2024-089879, filed on Jun. 3, 2024, with the Japan Patent Office, the disclosure of which is incorporated herein in its entirety by reference.

### TECHNICAL FIELD

The present disclosure relates to an information processing apparatus, a temperature control method, and a heat treatment apparatus.

### BACKGROUND

A heat treatment apparatus, for example, supplies gas into a processing container accommodating a wafer and performs a predetermined heat treatment on the wafer by heating using a heater. For temperature control, the heat treatment apparatus is provided with a temperature sensor (e.g., an outer T/C) that measures the temperature near the heater and a temperature sensor (e.g., an inner T/C) that measures the temperature inside the processing container, and controls heating by the heater, using the measured temperatures.

In the related art, there is known a technique in which heater power is adjusted so as to reduce the influence of accumulated films deposited inside the processing container of a heat treatment apparatus on the temperature of a wafer (see, e.g., Japanese Patent Application Laid-Open Publication No. 2024-027930).

### SUMMARY

An aspect of the present disclosure relates to an information processing apparatus that performs temperature control inside a processing container of a heat treatment apparatus. The information processing apparatus includes: a measured temperature acquisition unit that acquires a measured temperature of a member that holds a substrate to be processed and is carried into and out of the processing container, before the member is carried into the processing container; a prediction unit that outputs a predicted temperature of the substrate to be processed after the member is carried into the processing container, using the measured temperature of the member and a thermal simulation model of the heat treatment apparatus; and an adjustment unit that outputs a set temperature, adjusted based on the predicted temperature of the substrate to be processed, to a temperature controller that controls a heating unit to heat an interior of the processing container such that a measured temperature inside the processing container approaches the set temperature.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating a heat treatment apparatus according to an embodiment.

FIG. 2 is a cross-sectional view schematically illustrating a configuration of a heat treatment furnace.

FIG. 3 is a view illustrating an example of measurement points at which a non-contact thermometer measures temperature.

FIG. 4 is an explanatory view illustrating an example of temperature transition of a lid member, a boat, and a heat-retaining cylinder.

FIG. 5 is a functional block diagram illustrating an example of a controller of the heat treatment apparatus according to the present embodiment.

FIG. 6 is a flowchart illustrating an example of a processing sequence of a heat treatment apparatus that does not use a measured temperature obtained by a non-contact thermometer.

FIG. 7 is a flowchart illustrating an example of a processing sequence of the heat treatment apparatus according to the present embodiment that uses a measured temperature obtained by a non-contact thermometer.

FIG. 8 is a block diagram illustrating an example of a configuration of an information processing system according to the present embodiment.

FIG. 9 is a hardware configuration diagram illustrating an example of a computer.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment will be described with reference to the drawings.

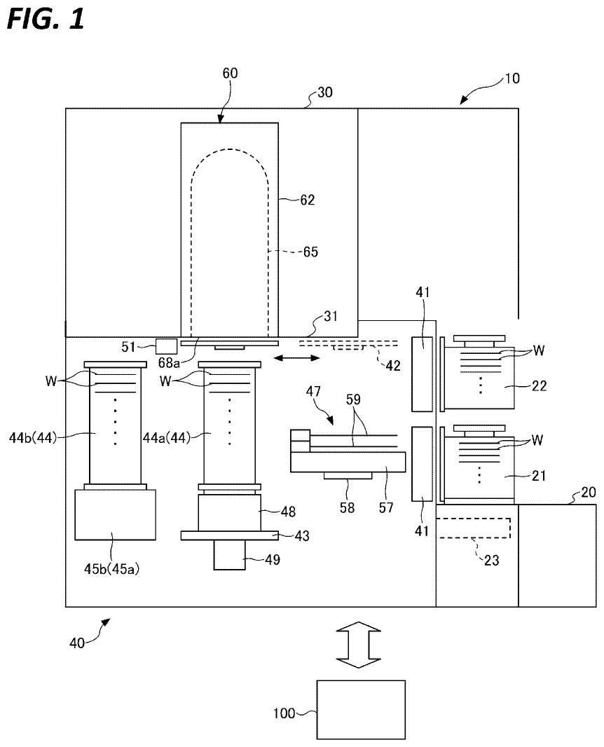

FIG. 1 is a vertical cross-sectional view schematically illustrating a heat treatment apparatus 10 according to the present embodiment. The heat treatment apparatus 10 illustrated in FIG. 1 may include a vertical heat treatment furnace 60, may hold and accommodate wafers W on a boat 44 at predetermined intervals along the vertical direction, and may perform various types of heat treatment, such as oxidation, diffusion, and low-pressure CVD, on the wafers W. In the following, an example will be described in which the surfaces of the wafers W inside a processing container 65 are heat-treated by supplying gas into the processing container 65. The wafers W are examples of substrates to be processed. The substrates to be processed are not limited to circular wafers W.

The heat treatment apparatus 10 illustrated in FIG. 1 includes a stage 20, a housing 30, and a control unit 100. The stage 20 may also be referred to as a load port. The stage 20 is provided at a front portion of the housing 30. The housing 30 includes a work region 40 and the heat treatment furnace 60.

The work region 40 may also be referred to as a loading area. The work region 40 is provided in a lower portion inside the housing 30. The heat treatment furnace 60 is provided inside the housing 30 and above the work region 40. A base plate 31 is provided between the work region 40 and the heat treatment furnace 60.

The stage 20 is configured to carry the wafers W into and out of the housing 30. Accommodation containers 21 and 22 are placed on the stage 20. The accommodation containers 21 and 22 are sealed containers (FOUPs) each equipped with a detachable lid (not illustrated) on the front side and capable of accommodating a plurality of wafers W (e.g., about 25 wafers) at predetermined intervals.

In addition, an alignment device 23 may be provided below the stage 20 to align cut-out portions (e.g., notches) formed on outer edges of the wafers W transferred by a transfer mechanism 47 in a single direction. The alignment device 23 may also be referred to as an aligner.

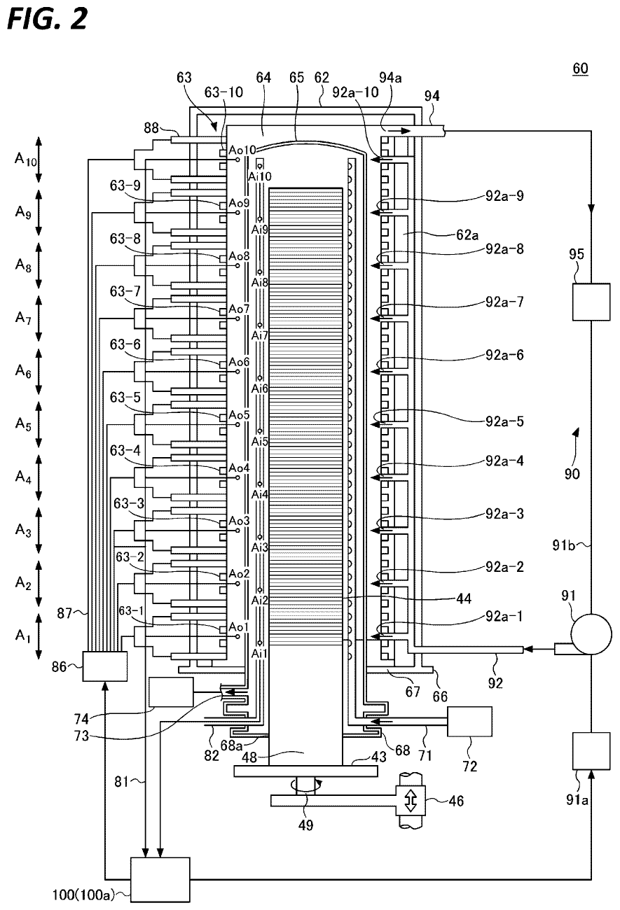

In the work region 40, the wafers W are transferred between the accommodation containers 21 and 22 and the boat 44. In addition, in the work region 40, the boat 44 is loaded into and unloaded from the processing container 65. The work region 40 is provided with a door mechanism 41, a shutter mechanism 42, a lid member 43, the boat 44, a base 45a, a base 45b, a lifting mechanism 46 illustrated in FIG. 2, the transfer mechanism 47, a heat-retaining cylinder 48, and a non-contact thermometer 51.

The door mechanism 41 removes lids of the accommodation containers 21 and 22 and opens the interiors of the accommodation containers 21 and 22 to be in communication with the work region 40. The shutter mechanism 42 is provided above the work region 40 so as to cover (or block) a furnace port 68a in order to suppress or prevent heat from the high-temperature interior of the furnace from being released into the work region 40 when the lid member 43 is open.

The lid member 43 includes a rotation mechanism 49. The heat-retaining cylinder 48 is provided on the lid member 43. The heat-retaining cylinder 48 prevents the boat 44 from being cooled by heat transfer to the lid member 43 and retains the heat of the boat 44.

The rotation mechanism 49 is attached to a lower portion of the lid member 43. The rotation mechanism rotates the boat 44. A rotation shaft of the rotation mechanism 49 penetrates the lid member 43 in an airtight manner and is configured to rotate a rotary table disposed on the lid member 43.

The lifting mechanism 46 vertically drives the lid member 43 when the boat 44 is carried into the processing container 65 from the work region 40 or carried out of the processing container 65 to the work region 40. When the boat 44 is lifted by the lifting mechanism 46 and is carried into the processing container 65, the lid member 43 is in contact with and seals the furnace port 68a.

The boat 44 on the lid member 43 may hold the wafers W inside the processing container 65 so as to be rotatable in a horizontal plane. The heat treatment apparatus 10 may include a plurality of boats 44. In the work region 40 illustrated in FIG. 1, boats 44a and 44b are provided. The work region 40 is further provided with bases 45a and 45b and a boat transfer mechanism.

The bases 45a and 45b are stages onto which the boats 44a and 44b are respectively transferred from the lid member 43. The boat transfer mechanism transfers the boat 44a or 44b from the lid member 43 onto the base 45a or 45b.

The boats 44a and 44b may be made of, for example, quartz, and are capable of supporting large-diameter wafers W, such as wafers having a diameter of 300 mm, in a horizontal state at predetermined vertical intervals (pitch). Each of the boats 44a and 44b includes a plurality of columns (e.g., three columns) provided between a top plate and a bottom plate. Each column is provided with claw portions for holding the wafers W. In addition, auxiliary columns may also be appropriately provided along with main columns.

The transfer mechanism 47 transfers the wafers W between the accommodation container 21 or 22 and the boat 44a or 44b. The transfer mechanism 47 includes a base 57, a lifting arm 58, and a plurality of transfer plates 59. The transfer plates 59 may also be referred to as forks.

The base 57 is configured to be liftable and rotatable. The lifting arm 58 is configured to be vertically movable (liftable) by, for example, a ball screw. The base 57 is provided on the lifting arm 58 so as to be horizontally rotatable.

The non-contact thermometer 51 measures the temperatures of the lid member 43, the boat 44, and the heat-retaining cylinder 48 in the work region 40. The non-contact thermometer 51 may be, for example, a radiation thermometer or a thermoviewer. The radiation thermometer is a thermometer that measures the temperature of an object in a non-contact manner by measuring the intensity of infrared radiation emitted from the object. The thermoviewer is a thermometer that measures the temperature distribution on the surface of an object in a non-contact manner. The non-contact thermometer 51 may also be a device that measures the temperature distribution on the surface of an object in a non-contact manner by utilizing infrared images captured by an infrared camera.

The non-contact thermometer 51 is provided at a position where the non-contact thermometer may measure the temperatures of the lid member 43, the boat 44, and the heat-retaining cylinder 48 in the work region 40. The non-contact thermometer 51 illustrated in FIG. 1 is provided above the work region 40 in order to measure the temperatures of the lid member 43, the boat 44, and the heat-retaining cylinder 48 in the work region 40 from above. The non-contact thermometer 51 of FIG. 1 may be installed at a location less susceptible to temperature increases. The non-contact thermometer 51 of FIG. 1 may also be air-cooled by an inert gas or water-cooled, if necessary.

FIG. 2 is a cross-sectional view schematically illustrating a configuration of the heat treatment furnace 60. The heat treatment furnace 60 illustrated in FIG. 2 is an example of a vertical furnace that accommodates a plurality of thin, disc-shaped wafers W and perform a predetermined heat treatment. The heat treatment furnace 60 includes a jacket 62, a heater 63, a space 64, and a processing container 65.

The processing container 65 accommodates the wafers W held on the boat 44. The wafers W accommodated in the processing container 65 undergo heat treatment. The processing container 65 may be made of, for example, quartz and has a vertically elongated shape. The processing container 65 is supported on a base plate 66 via a lower manifold 68. A gas is supplied into the processing container 65 through an injector 71 from the manifold 68. The injector 71 supplies the gas into the processing container 65 through blowing portions (holes). The injector 71 is connected to a gas source 72. The gas supplied to the processing container 65 is exhausted through an exhaust port 73 by an exhaust system 74 including a vacuum pump capable of pressure reduction control.

The lid member 43 closes a furnace port 68a located at the lower portion of the manifold 68 when the boat 44 is loaded into the processing container 65. The lid member 43 is configured to be liftable by the lifting mechanism 46. The heat-retaining cylinder 48 is placed on the upper portion of the lid member 43. The boat 44, which supports a plurality of wafers W vertically at predetermined intervals, is placed on the upper portion of the heat-retaining cylinder 48.

The jacket 62 is provided so as to cover the periphery of the processing container 65 and defines the space 64 around the processing container 65. Like the processing container 65, the jacket 62 has a cylindrical shape. The jacket 62 is supported by the base plate 66. Inside the jacket 62 and outside the space 64, a heat-insulating material 62a including, for example, glass wool, may be provided.

The heater 63 is provided so as to cover the periphery of the processing container 65. For example, the heater 63 is provided inside the jacket 62 and outside the space 64. The heater 63 heats the processing container 65 and also heats the wafers W held on the boat 44, that is, the wafers W inside the processing container 65. In this way, the heater 63 functions as a heating unit that heats the wafers W.

The heater 63 includes, for example, a heat-generating resistor such as a carbon wire, and is capable of controlling the temperature of gas flowing through the space 64 and also controlling the temperature inside the processing container 65 to a predetermined level (e.g., 50° C. to 1,200° C.).

The space 64 and the space inside the processing container 65 are divided along the vertical direction into a plurality of unit regions, for example, ten unit regions A1, A2, A3, A4, A5, A6, A7, As, A9, and A10. The heater 63 is divided into heaters 63-1 to 63-10 to correspond to the respective unit regions A1 to A10 along the vertical direction.

Each of the heaters 63-1 to 63-10 is configured to independently control heating for the respective unit regions A1 to A10 based on the output (heater power) of a heater power controller 86 including, for example, a thyristor.

FIG. 2 illustrates an example in which the space 64 and the space inside the processing container 65 are divided into ten unit regions along the vertical direction. The number of divisions of the unit regions is not limited to ten, and the space 64 and the space inside the processing container 65 may be divided into a number other than ten. Although FIG. 2 illustrates an example in which the regions are evenly divided, the present disclosure is not limited thereto, and the vicinity of the furnace port 68a, where temperature variations are significant, may be divided into finer regions. The heaters 63 only need to be provided at different positions along the vertical direction, and may not be provided to correspond to the respective unit regions A1 to A10 in a one-to-one manner.

In the space 64, heater temperature sensors Ao1 to Ao10 are provided as outer T/Cs to measure temperatures corresponding to the respective unit regions A₁ to A₁₀. In the space inside the processing container 65, processing container interior temperature sensors Ai1 to Ai10 are also provided as inner T/Cs to measure temperatures corresponding to the respective unit regions A₁ to A₁₀. The heater temperature sensors Ao1 to Ao10 and the processing container interior temperature sensors Ai1 to Ai10 measure temperatures so as to identify the temperature distribution along the vertical direction. The temperatures measured by the processing container interior temperature sensors Ai1 to Ai10 are an example of measured temperatures inside the processing container 65.

The measured temperatures obtained by the heater temperature sensors Ao1 to Ao10 are input to the control unit 100 via respective lines 81. The measured temperatures obtained by the processing container internal temperature sensors Ai1 to Ai10 are input to the control unit 100 via respective lines 82. The control unit 100, to which the measured temperatures are input, controls the heater power supplied from a heater power controller 86 to the heaters 63-1 to 63-10, as described later. In addition, as described later, the heater power controller 86 supplies the heater power, adjusted by the control unit 100, to the heaters 63-1 to 63-10 via heater output lines 87 and heater terminals 88.

The heat treatment furnace 60 may include a cooling mechanism 90 that cools the processing container 65. The cooling mechanism 90 includes, for example, a blower 91, a blower duct 92, and an exhaust duct 94. The blower 91 may also be referred to as a blower fan.

The blower 91 cools the processing container 65 by blowing a cooling gas, such as air, into the space 64 in which the heater 63 is provided. The blower duct 92 delivers the cooling gas from the blower 91 to the heater 63. The blower duct 92 is connected to each of blowing holes 92a-1 to 92a-10 and supplies the cooling gas to the space 64.

The exhaust duct 94 serves to discharge air from the space 64. An exhaust port 94a is provided in the space 64 to discharge the cooling gas from the space 64. One end of the exhaust duct 94 is connected to the exhaust port 94a.

As illustrated in FIG. 2, the heat treatment furnace 60 may include a heat exchanger 95 provided in the middle of the exhaust duct 94, and the other end of the exhaust duct 94 may be connected to the suction side of the blower 91. In such a case, the cooling gas exhausted through the exhaust duct 94 may be circulated without being discharged to a factory exhaust system, by being returned to the blower 91 after undergoing heat exchange through the heat exchanger 95. In that case, the cooling gas may be circulated via an air filter (not illustrated). Alternatively, the cooling gas discharged from the space 64 may be discharged to the factory exhaust system through the exhaust duct 94 and the heat exchanger 95.

The blower 91 may be configured to control the airflow of the blower 91 by controlling power supplied from a power supply unit 91a including, for example, an inverter, based on an output signal from the control unit 100.

The control unit 100 may be implemented by, for example, a computer 500 as will be described later. The control unit 100 reads a program stored in a storage device, and executes heat treatment by sending a control signal to each component constituting the heat treatment apparatus 10 in accordance with the program. In addition, the control unit 100 may more accurately predict a temperature change of the wafers W after being loaded into the processing container 65 by adjusting the heater power supplied from the heater power controller 86 to the heater 63, as will be described later.

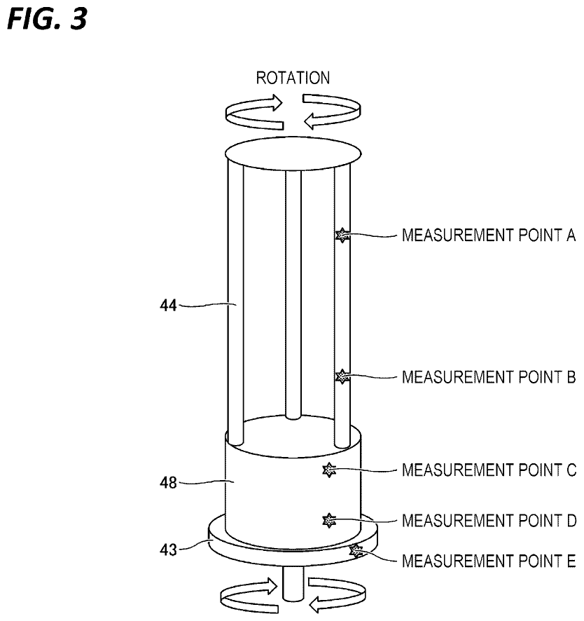

FIG. 3 is a view illustrating examples of measurement points at which the non-contact thermometer 51 measures temperature. Measurement points A and B are examples of measurement points set on a column of the boat 44. Measurement points C and D are examples of measurement points set on the heat-retaining cylinder 48. Measurement point E is an example of a measurement point set on the lid member 43.

The measurements at measurement points A to E by the non-contact thermometer 51 may be performed for all-around measurements by rotating the lid member 43, the boat 44, and the heat-retaining cylinder 48. For example, the all-around measurements at measurement points A and B by the non-contact thermometer 51 measure, for example, a temperature increase range on the columns of the boat 44. The all-around measurements at measurement points C and D by the non-contact thermometer 51 measure the temperatures of the entire circumference of the heat-retaining cylinder 48. The all-around measurements at measurement point E by the non-contact thermometer 51 measure the temperatures of the entire circumference of the lid member 43. For the all-around measurements at measurement points C to E by the non-contact thermometer 51, an averaged measured temperature may be used.

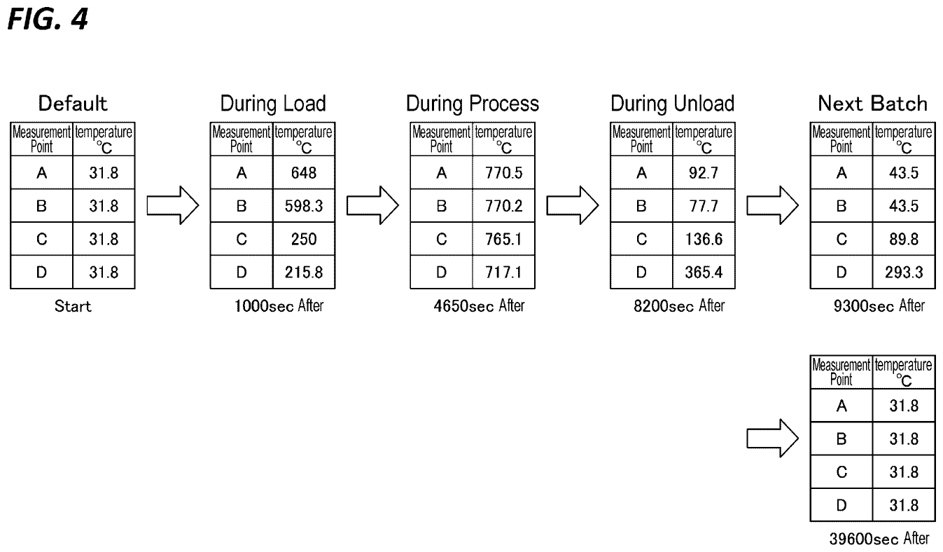

As illustrated by the temperature transitions in FIG. 4, the temperatures of the lid member 43, the boat 44, and the heat-retaining cylinder 48 increase during loading (Load) into the processing container 65, and decrease during unloading (Unload) from the processing container 65. FIG. 4 is an explanatory view illustrating an example of temperature transitions of the lid member 43, the boat 44, and the heat-retaining cylinder 48. FIG. 4 illustrates the temperature transitions at measurement points A to D, among the measurement points A to E illustrated in FIG. 3.

At the start state (Default) illustrated in FIG. 4, the temperatures at measurement points A to D are all set to 31.8° C. During loading, the temperatures at measurement points A to D increase due to heating by the heater 63. During loading In FIG. 4, the temperature rise rates at measurement points A to D vary due to differences in heat capacities between the boat 44 and the heat-retaining cylinder 48. Such differences in temperature rise rates during loading may cause variation in the temperature change of the wafers W between the loading and the start of processing (Process). Accordingly, in the current recipe, the time from loading to the start of processing is set to be longer in order to suppress variation in the temperature of the wafers W at the start of processing.

During unloading, the temperatures at measurement points A to D decrease. In FIG. 4, during unloading, variations in the temperature decrease rates at measurement points A to D occur due to the difference in heat capacities between the boat 44 and the heat-retaining cylinder 48. The lid member 43, the boat 44, and the heat-retaining cylinder 48 are examples of components having relatively large heat capacities. The heat-retaining cylinder 48 is an example of a component having a larger heat capacity than the lid member 43 and the boat 44. As illustrated in FIG. 4, the temperatures at measurement points A to D during unloading may vary depending on the time interval from the unloading to the loading of the next batch.

FIG. 4 illustrates an example in which the time interval from the initial state to the next batch is 9,300 seconds (2 hours and 35 minutes). In the meantime, when the start of the next batch is to be waited until the temperatures at measurement points A to D become equal to those in the initial state, 39,600 seconds (11 hours) would be required.

When the time interval from the unloading to the loading of the next batch becomes longer, the temperatures at measurement points C and D of the heat-retaining cylinder 48, which has a large heat capacity, significantly decrease. When the time interval from the unloading to the loading of the next batch becomes longer, the temperature of the heat-retaining cylinder 48 significantly decreases due to its large heat capacity, which may result in a difference in the temperature change of the wafers W from the loading to the start of processing.

Accordingly, in the heat treatment apparatus 10 according to the present embodiment, the temperature before loading of a component having a relatively large heat capacity is measured by the non-contact thermometer 51, and is used to predict the temperature of the wafers W after loading, thereby improving the accuracy of prediction of the temperature of the wafers W after loading. By improving the accuracy of the predicted temperature of the wafers W after loading, the heat treatment apparatus 10 according to the present embodiment adjusts the heater power supplied to the heater 63, as described later, based on the predicted temperature of the wafers W, so as to prevent variation in the temperature of the wafers W at the start of processing.

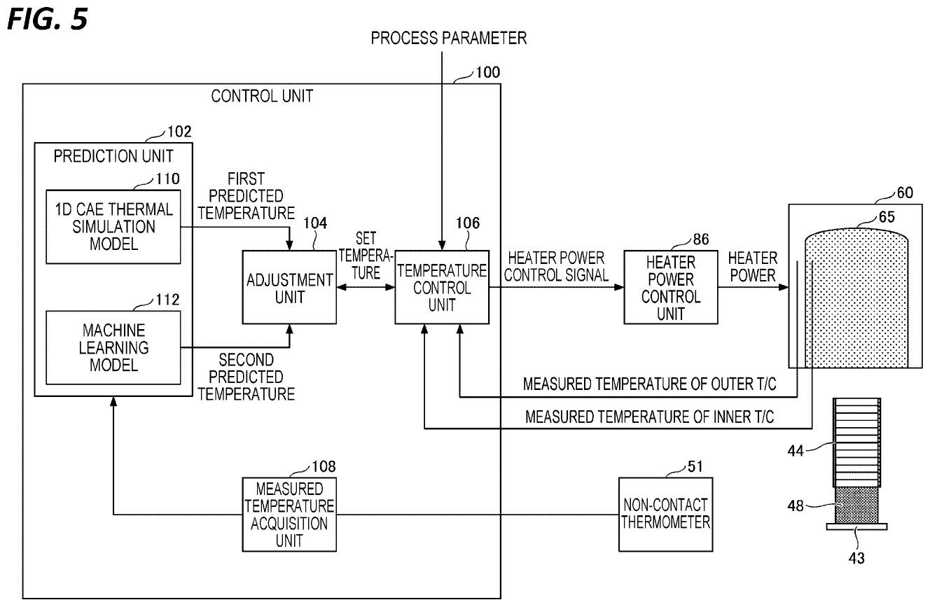

The control unit 100 of the heat treatment apparatus 10 may be implemented with, for example, a functional configuration as illustrated in FIG. 5. FIG. 5 is a functional block diagram illustrating an example of the control unit 100 of the heat treatment apparatus 10 according to the present embodiment. Components not necessary for the description of the present embodiment are omitted from the diagram in FIG. 5.

The control unit 100 implements a prediction unit 102, an adjustment unit 104, a temperature controller 106, and a measured temperature acquisition unit 108 by executing a program. The prediction unit 102 uses a 1D CAE thermal simulation model 110 and a machine learning model 112.

The control unit 100 is an example of an information processing apparatus that performs temperature control inside the processing container 65 of the heat treatment apparatus 10. The measured temperature acquisition unit 108 acquires a measured temperature of a member that holds the wafers W for heat treatment and is carried into and out of the processing container 65 (e.g., the lid member 43, the boat 44, and the heat-retaining cylinder 48) before the member is carried into the processing container 65. The measured temperature before the member is carried into the processing container 65 is acquired from the non-contact thermometer 51.

The measured temperature before the member is carried into the processing container 65 may be the temperature of at least one measurement point of the heat-retaining cylinder 48, which has the largest heat capacity. In addition, the measured temperature before the member is carried into the processing container 65 may include at least one of a temperature of at least one measurement point of the boat 44 and a temperature of at least one measurement point of the lid member 43, in addition to the temperature of the at least one measurement point of the heat-retaining cylinder 48.

The prediction unit 102 outputs the predicted temperature of the wafers W after the member that holds the wafers W for heat treatment and is carried into and out of the processing container 65 is carried into the processing container 65, using the measured temperature of the member and a thermal simulation model of the heat treatment apparatus 10.

For example, the prediction unit 102 in FIG. 5 outputs a first predicted temperature of the wafers W after the member is carried into the processing container 65, using a 1D CAE thermal simulation model 110 of the heat treatment apparatus 10. The 1D CAE thermal simulation model 110 of the heat treatment apparatus 10 is a physical model that reproduces the configuration of FIG. 2. The 1D CAE thermal simulation model 110 is a thermal model that outputs predicted temperatures of the member and the wafer W within the processing container 65 in accordance with the heater power determined by the temperature controller 106. In the 1D CAE thermal simulation model 110, the relationships of heat transfer and specific heat among components such as the member and the wafer W in the processing container 65 are modeled.

In the heat treatment apparatus 10 according to the present embodiment, the accuracy of the first predicted temperature of the wafers W after the member is carried into the processing container 65 is improved by feeding the measured temperature of the member before being carried into the processing container 65 back to the 1D CAE thermal simulation model 110. Thus, in the 1D CAE thermal simulation model 110, heat transfer paths of radiant heat from components such as the lid member 43, the boat 44, and the heat-retaining cylinder 48 are added, and the accuracy of the first predicted temperature of the wafers W is enhanced.

The 1D CAE thermal simulation model 110 of the heat treatment apparatus 10 may calculate a difference between a measured temperature obtained when a process is executed according to process parameters and a predicted temperature predicted according to the process parameters, and may be adjusted to reduce the difference.

By using the 1D CAE thermal simulation model 110 of the heat treatment apparatus 10, the control unit 100 of the heat treatment apparatus 10 may implement a so-called digital twin, in which changes in the temperature in the real (physical) space within the processing container 65 during execution of heat treatment in the heat treatment apparatus 10 are reproduced in a virtual (cyber) space in a linked manner. With the digital twin, the state of temperature of the wafers W within the processing container 65 of the heat treatment apparatus 10 may be reproduced in the virtual space while the heat treatment is being executed in the heat treatment apparatus 10.

The prediction unit 102 outputs a second predicted temperature of the wafers W after the member is carried into the processing container 65, using the machine learning model 112. The machine learning model 112 is a model (thermal model) trained through machine learning on the relationship among a set temperature, a film formation processing time, and a film formation result, when the heat treatment is a film formation process. The 1D CAE thermal simulation model 110 may be used for machine learning of the machine learning model 112. In the case where the heat treatment is, for example, a film formation process, the machine learning model 112 may be used for a function of optimizing the set temperature and the film formation processing time (process optimizer function) while adjusting the relationship among the set temperature, the film formation processing time, and the film formation result through machine learning. The process optimizer function may calculate, for example, process parameters that approach a target film thickness by feeding back the film formation result. By repeatedly learning this calculation, the process optimizer may optimize the process parameters so as to approach the target film thickness. In addition, the process optimizer may optimize the set temperature so as to suppress variation in the temperature of the wafers W at the start of film formation processing.

The adjustment unit 104 outputs a set temperature, adjusted based on the predicted temperature of the wafers W, to the temperature controller 106. The adjustment unit 104 may output a set temperature, adjusted based on the first predicted temperature of the wafers W, to the temperature controller 106, may output a set temperature, adjusted based on the second predicted temperature of the wafers W, to the temperature controller 106, or may output a set temperature, adjusted based on both the first and second predicted temperatures of the wafers W, to the temperature controller 106.

In addition, the adjustment unit 104 may adjust the set temperature to be output to the temperature controller 106 such that the time from when the member is carried into the processing container 65 to when heat treatment is started according to a recipe is made uniform.

The temperature controller 106 acquires a set temperature of the wafers W included in process parameters for the process to be executed in the heat treatment apparatus 10. The temperature controller 106 outputs the set temperature of the wafers W to the adjustment unit 104 and acquires the set temperature adjusted by the adjustment unit 104. The temperature controller 106 also acquires the temperatures measured by the outer T/C and the inner T/C.

The temperature controller 106 performs feedback control of the heater power controller 86 such that the measured temperature by measured the inner T/C in the processing container 65 approaches the set temperature adjusted by the adjustment unit 104. The heater power controller 86 supplies heater power to the heater 63 in accordance with a heater power control signal output from the temperature controller 106.

The temperatures measured by the outer T/C and the inner T/C may also be used in the processing performed by the prediction unit 102 and the adjustment unit 104. In addition, the heater power determined by the temperature controller 106 may also be used in the processing performed by the prediction unit 102 and the adjustment unit 104. The control unit 100 executes processing in the heat treatment apparatus 10 in accordance with process parameters.

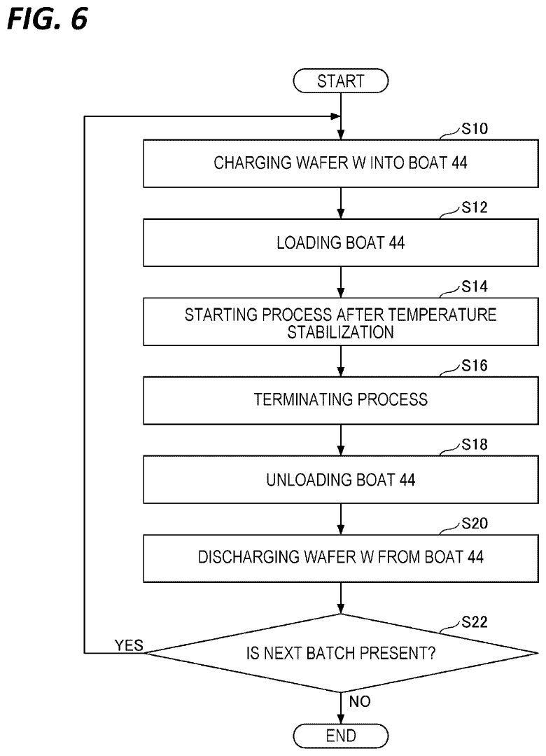

FIG. 6 is a flowchart illustrating an example of a processing sequence of the heat treatment apparatus 10 that does not use the temperature measured by the non-contact thermometer 51.

In step S10, the heat treatment apparatus 10 transfers (charges) wafers W, for example, from the accommodation container 21 or 22 to the boat 44.

In step S12, the heat treatment apparatus 10 carries (loads) the boat 44, on which the wafers W are charged, into the processing container 65.

In step S14, the heat treatment apparatus 10 starts a process according to a recipe after temperature stabilization within the processing container 65. In step S16, the heat treatment apparatus 10 terminates the process.

In step S18, the heat treatment apparatus 10 carries (unloads) the boat 44, on which the wafers W are charged, out of the processing container 65.

In step S20, the heat treatment apparatus 10 transfers (discharges) the wafers W from the boat 44 to the accommodation container 21 or 22.

In step S22, when there is a next batch to be processed, the heat treatment apparatus 10 returns to step S10 to perform processing for the next batch. If there is no next batch to be processed, the heat treatment apparatus 10 terminates the processing of the flowchart in FIG. 6.

In the processing of the flowchart in FIG. 6, as the time interval from the unloading of the boat 44 in step S18 to the loading of the boat 44 in step S12 of the next batch increases, the temperatures of the lid member 43, the boat 44, and the heat-retaining cylinder 48 decrease. As described above, the lid member 43, the boat 44, and the heat-retaining cylinder 48 have relatively large heat capacities, and variation may occur in the time required to reach a stabilized temperature state of the wafers W within the processing container 65. When variation occurs in the temperature of the wafers W within the processing container 65 at the start of processing, a batch processing result such as a film formation result may fluctuate. Accordingly, in the current recipe, the time from loading to the start of processing is set to be long in order to suppress variation in the temperature of the wafers W at the start of processing and to suppress fluctuation in a batch processing result such as a film formation result.

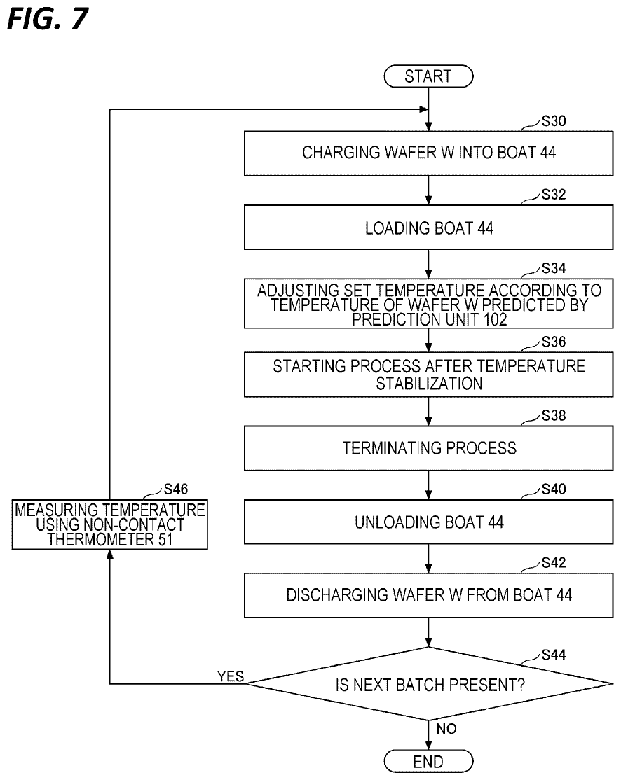

FIG. 7 is a flowchart illustrating an example of a processing sequence of the heat treatment apparatus 10 according to the present embodiment that uses the temperatures measured by the non-contact thermometer 51.

In step S30, the heat treatment apparatus 10 charges wafers W, for example, from the accommodation container 21 or 22 to the boat 44.

In step S32, the heat treatment apparatus 10 loads the boat 44, on which the wafers W are charged, into the processing container 65.

In step S34, the prediction unit 102 of the control unit 100 outputs a predicted temperature of the wafers W after the member that holds the wafers W for heat treatment and is carried into and out of the processing container 65 is carried into the processing container 65, using the measured temperature of the member and a thermal simulation model of the heat treatment apparatus 10, as described above.

The adjustment unit 104 outputs a set temperature, adjusted based on the predicted temperature of the wafers W, to the temperature controller 106. As described above, the set temperature adjusted by the adjustment unit 104 is adjusted so that heating by the heater 63 does not cause variation in the temperature of the wafers W within the processing container 65 at the start of processing. Accordingly, in the heat treatment apparatus 10 according to the present embodiment, variation in the temperature of the wafers W within the processing container 65 at the start of processing is suppressed.

In step S36, the heat treatment apparatus 10 starts a process according to a recipe after temperature stabilization within the processing container 65. In step S38, the heat treatment apparatus 10 terminates the process.

In step S40, the heat treatment apparatus 10 unloads the boat 44, on which the wafers W are charged, out of the processing container 65.

In step S42, the heat treatment apparatus 10 discharges the wafers W from the boat 44 to the accommodation container 21 or 22.

In step S44, when there is a next batch to be processed, the heat treatment apparatus 10 performs the processing of step S46. In step S46, the non-contact thermometer 51 of the heat treatment apparatus 10 measures the temperatures of components having large heat capacities, such as the lid member 43, the boat 44, and the heat-retaining cylinder 48, and outputs the measured temperatures to the control unit 100. After the processing of step S46, the heat treatment apparatus 10 returns to step S30 and performs the processing for the next batch. The timing of the temperature measurement by the non-contact thermometer 51 illustrated in FIG. 7 is merely an example, and the temperature measurement may be performed during or after the processing of step S40. When there is no next batch to be processed in step S44, the heat treatment apparatus 10 terminates the processing of the flowchart in FIG. 7.

In the processing of the flowchart in FIG. 7, the accuracy of the predicted temperature of the wafers W after loading may be improved by using the measured temperature of a member having a large heat capacity, which is actually measured by the non-contact thermometer 51, in predicting the temperature of the wafers W within the processing container 65.

According to the processing of the flowchart in FIG. 7, even when the time interval from the unloading of the boat 44 in step S40 to the loading of the boat 44 in step S32 of the next batch becomes longer, the heater 63 may be controlled so that variation in the temperature of the wafers W at the start of processing does not occur. As a result, in the heat treatment apparatus 10 according to the present embodiment, variation in the temperature of the wafers W at the start of processing may be suppressed, thereby suppressing fluctuation in a batch processing result such as a film formation result.

In addition, according to the processing of the flowchart in FIG. 7, the time interval from loading to the start of processing may be made uniform by controlling the heater 63 so that variation does not occur in the time required to reach a stabilized temperature state of the wafers W within the processing container 65. As a result, in the heat treatment apparatus 10 according to the present embodiment, since it is not necessary to set the time interval from loading to the start of processing to be long, an improvement in productivity may be expected.

In the above-described embodiment, the processing performed by the control unit 100 of the heat treatment apparatus 10 may be performed by another information processing apparatus communicably connected to the control unit 100 via data communication.

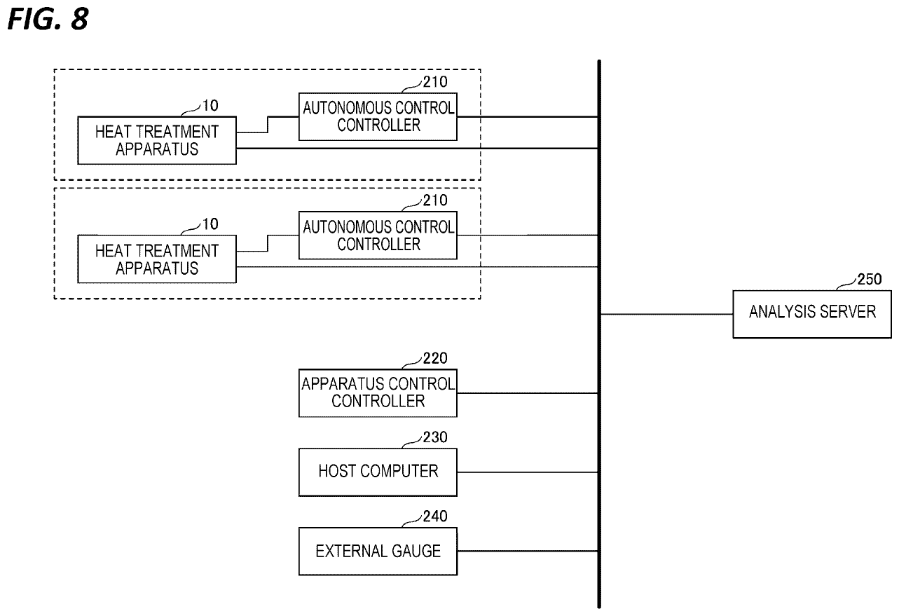

FIG. 8 is a block diagram illustrating an exemplary configuration of an information processing system according to the present embodiment. The information processing system illustrated in FIG. 8 includes heat treatment apparatuses 10, autonomous control controllers 210, an apparatus control controller 220, a host computer 230, an external gauge 240, and an analysis server 250.

The heat treatment apparatuses 10, the autonomous control controllers 210, the apparatus control controller 220, the host computer 230, the external gauge 240, and the analysis server 250 are communicably connected via a network such as a local area network (LAN).

The heat treatment apparatuses 10 each execute a process according to control commands (process parameters) output from the apparatus control controller 220. Each of the autonomous control controllers 210 is a controller that autonomously controls a heat treatment apparatus 10 and performs, for example, simulation of the process state that is being executed in the heat treatment apparatus 10 using a simulation model.

Each heat treatment apparatus 10 is provided with an autonomous control controller 210. The autonomous control controller 210 performs at least a part of the processing performed by the control unit 100 in the above-described embodiment.

The apparatus control controller 220 is a controller having a computer configuration for controlling the heat treatment apparatuses 10. The apparatus control controller 220 outputs process parameters for controlling the control components of the heat treatment apparatuses 10 to the heat treatment apparatuses 10. The host computer 230 is an example of a man-machine interface (MMI) that receives instructions for the heat treatment apparatuses 10 from an operator and provides information on the heat treatment apparatuses 10 to the operator.

The external gauge 240 is a measuring instrument that measures a result after execution of a process according to process parameters, such as a film thickness measuring instrument, a sheet resistance measuring instrument, or a particle measuring instrument. For example, the external gauge 240 measures the state of film formation on wafers W, such as a monitor wafer.

The analysis server 250 performs, for example, data analysis necessary for processing executed by the autonomous control controller 210. The analysis server 250 may train the machine learning models 112 of the heat treatment apparatuses 10 using data collected from a plurality of heat treatment apparatuses 10.

The information processing system illustrated in FIG. 8 is merely an example, and various other system configurations may be adopted depending on the purpose and application. In addition, the classification of apparatuses such as the heat treatment apparatus 10, the autonomous control controller 210, the apparatus control controller 220, the host computer 230, the external gauge 240, and the analysis server 250 in FIG. 8 is merely an example.

For example, the information processing system may have various configurations, such as a configuration in which at least two of the heat treatment apparatus 10, the autonomous control controller 210, the apparatus control controller 220, the host computer 230, the external gauge 240, and the analysis server 250 are integrated into a single unit or divided into further separate components.

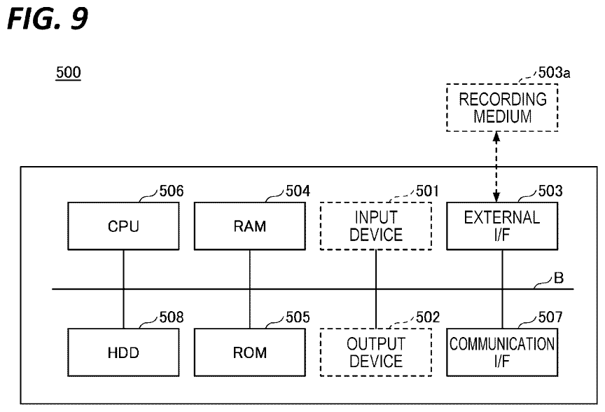

The autonomous control controllers 210, the apparatus control controller 220, the host computer 230, and the analysis server 250 of the information processing system illustrated in FIG. 8 may be implemented by a computer having a hardware configuration as illustrated in FIG. 9. The control unit 100 of the heat treatment apparatus 10 described above may also be implemented by a computer having the hardware configuration illustrated in FIG. 9. FIG. 9 is a hardware configuration diagram illustrating an example of a computer.

The autonomous control controller 210, the apparatus control controller 220, the host computer 230, the analysis server 250, and the control unit 100 are examples of information processing apparatuses that perform temperature control inside the processing container 65 of the heat treatment apparatus 10.

The computer 500 in FIG. 9 includes an input device 501, an output device 502, an external interface (I/F) 503, a random access memory (RAM) 504, a read only memory (ROM) 505, a central processing unit (CPU) 506, a communication I/F 507, and a hard disk drive (HDD) 508, all of which are interconnected via a bus B. The input device 501 and the output device 502 may be connected and used only when necessary.

The input device 501 includes, for example, a keyboard, a mouse, or a touch panel, and is used by an operator to input various operation signals. The output device 502 is, for example, a display, and is used to present processing results from the computer 500. The communication I/F 507 is an interface that connects the computer 500 to a network. The HDD 508 is an example of a non-volatile storage device that stores programs and data.

The external I/F 503 functions as an interface with external devices. The computer 500 may read from and/or write to a recording medium 503a, such as a secure digital (SD) memory card, via the external I/F 503. The ROM 505 is an example of a non-volatile semiconductor memory (storage device) in which programs and data are stored. The RAM 504 is an example of a volatile semiconductor memory (storage device) that temporarily stores programs and data.

The CPU 506 is a processor that reads programs and data from storage devices such as the ROM 505 and the HDD 508 onto the RAM 504 and executes processes to implement overall control and functions of the computer 500.

The autonomous control controller 210, the apparatus control controller 220, the host computer 230, and the analysis server 250 of the information processing system illustrated in FIG. 8 may implement various functions through, for example, the hardware configuration of the computer 500 illustrated in FIG. 9. The control unit 100 of the heat treatment apparatus 10 described above may also implement various functions through, for example, the hardware configuration of the computer 500 illustrated in FIG. 9.

The autonomous control controller 210 implements a digital twin of the actual heat treatment apparatus 10 and its simulated heat treatment apparatus 10 by executing a simulation of a physical model using process parameters of a simulated heat treatment apparatus 10. By comparing, in real time, information (e.g., a measured temperature) obtained from the heat treatment apparatus 10 during execution of heat treatment with information (e.g., a predicted temperature) obtained from simulation, the temperature of wafers W at the start of heat treatment may be predicted, and processing for reducing fluctuation in the film formation result may be executed.

By using the techniques of the above-described embodiment, the heat treatment apparatus 10 according to the present embodiment may suppress variation in the temperature of wafers W at the start of processing and may also shorten the time from loading to the start of processing, thereby contributing to productivity improvement.

The measurement points at which the non-contact thermometer 51 measures temperature are factors that directly affect variation in the temperature of wafers W at the start of processing. By using the temperature of the member measured by the non-contact thermometer 51 before the boat 44 is loaded for predicting the temperature of wafers W within the processing container 65, the heat treatment apparatus 10 according to the present embodiment may accurately predict the temperature of the wafers W within the processing container 65.

According to the present disclosure, a temperature change of a substrate to be processed after being carried into the processing container may be predicted more accurately.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
temperature acquisition circuitry configured to acquire a measured temperature of a member that holds a substrate to be processed and is carried into and out of a processing container of a heat treatment apparatus, before the member is carried into the processing container;
prediction circuitry configured to output a predicted temperature of the substrate to be processed after the member is carried into the processing container, using the measured temperature of the member and a thermal simulation model of the heat treatment apparatus; and
adjustment circuitry configured to output a set temperature, adjusted based on the predicted temperature of the substrate to be processed, to a temperature controller that controls a heater to heat an interior of the processing container such that a measured temperature inside the processing container approaches the set temperature.

2. The information processing apparatus of claim 1, wherein the measured temperature of the member includes a measured temperature of a heat-retaining body that retains heat for a holder of the substrate to be processed.

3. The information processing apparatus of claim 2, wherein the measured temperature of the member further includes a measured temperature of the holder of the substrate to be processed and a measured temperature of a lid on which the holder is placed.

4. The information processing apparatus of claim 1, wherein the measured temperature acquisition circuitry acquire the measured temperature of the member by using a non-contact thermometer.

5. The information processing apparatus of claim 1, wherein the adjustment circuitry adjust the set temperature to match a time from when the member is carried into the processing container until the heat treatment according to a recipe is started.

6. The information processing apparatus of claim 1, wherein the prediction unit:
output a first predicted temperature of the substrate to be processed after the member is carried into the processing container by using a 1D CAE thermal simulation model of the heat treatment apparatus, and
output a second predicted temperature of the substrate to be processed after the member is carried into the processing container by using a trained machine learning model of the heat treatment apparatus.

7. A temperature control method comprising:
acquiring a measured temperature of a member that holds a substrate to be processed and is carried into and out of the processing container of a heat treatment apparatus, before the member is carried into the processing container;
outputting a predicted temperature of the substrate to be processed after the member is carried into the processing container, using the measured temperature of the member and a thermal simulation model of the heat treatment apparatus; and
outputting a set temperature, adjusted based on the predicted temperature of the substrate to be processed, to a temperature controller that controls a heater to heat an interior of the processing container such that a measured temperature inside the processing container approaches the set temperature.

8. A heat treatment apparatus comprising:
a processing container configured to perform heat treatment on a substrate to be processed;
a member configured to hold the substrate to be processed and be carried into and out of the processing container;
first measured temperature output circuitry configured to output a measured temperature of the member before the member is carried into a processing container;
second measured temperature output circuitry configured to output a measured temperature inside the processing container after the member is carried into the processing container;
prediction circuitry configured to output a predicted temperature of the substrate to be processed after the member is carried into the processing container, using the measured temperature of the member and a thermal simulation model of the heat treatment apparatus; and
adjustment circuitry configured to output a set temperature, adjusted based on the predicted temperature of the substrate to be processed, to a temperature controller that controls a heater to heat an interior of the processing container such that a measured temperature inside the processing container approaches the set temperature.
